(19) United States
(12) Patent Application Publication
(10) Pub. No.: US 2024/0353525 A1
(43) Pub. Date: Oct. 24, 2024

(54) SENSOR AND FABRICATION METHOD THEREOF

(71) Applicant: Shanghai Tianma Micro-electronics Co., Ltd., Shanghai (CN)

(72) Inventors: Yifan XING, Shanghai (CN); Feng QIN, Shanghai (CN); Baiquan LIN, Shanghai (CN); Xiaonan HAN, Shanghai (CN); Yifan BAO, Shanghai (CN); Ping SU, Shanghai (CN); Shengwei DAI, Shanghai (CN); Zhenyu JIA, Shanghai (CN); Zhen LIU, Shanghai (CN); Xiaojun CHEN, Shanghai (CN)

(21) Appl. No.: 18/224,786

(22) Filed: Jul. 21, 2023

(30) Foreign Application Priority Data
Apr. 21, 2023 (CN) 202310438908.X

(51) Int. Cl. G01S 7/03; G01S 13/02; H01P 1/18; H01P 11/00

(52) U.S. Cl. CPC G01S 7/03; G01S 13/02; H01P 1/18; H01P 11/00

(57) ABSTRACT

A sensor and its fabrication method are provided. The sensor includes a first glass substrate, a circuit layer on a side of the first glass substrate, and a radio frequency processing chip on a side of the circuit layer away from the first glass substrate.

### CROSS-REFERENCE TO RELATED APPLICATION

This application claims the priority of Chinese Patent Application No. 202310438908.X, filed on Apr. 21, 2023, the content of which is incorporated herein by reference in its entirety.

### TECHNICAL FIELD

The present disclosure generally relates to the field of radar technology and, more particularly, relates to a sensor and its fabrication method.

### BACKGROUND

A millimeter wave radar has the characteristics of high resolution, wide frequency band, and strong anti-interference ability. Electromagnetic wave emitted by a radar system is reflected after encountering obstacles. By capturing reflected signals, the radar system is able to determine the distance, speed and angle of an object. As an effective means of preventing traffic accidents, vehicle-mounted millimeter wave radars have been valued by major automobile manufacturers.

The millimeter wave radar is a radar that works in the millimeter wave band. Usually, millimeter wave refers to the 30-300 GHz frequency domain (wavelength of 1-10 mm). The wavelength of millimeter wave is between microwave and centimeter wave, and the millimeter wave radar has some advantages of a microwave radar and a photoelectric radar. Therefore, the millimeter-wave radar can be applied to scenes with a long detection distance. Specifically, the millimeter-wave radar is suitable for kilometers and preliminary detection.

However, existing millimeter-wave radar sensors have a problem of poor detection accuracy.

### SUMMARY

One aspect of the present disclosure provides a sensor. The sensor includes a first glass substrate, a circuit layer on a side of the first glass substrate, and a radio frequency processing chip on a side of the circuit layer away from the first glass substrate.

Another aspect of the present disclosure provides a fabrication method of a sensor. The method includes: providing a first glass substrate; forming a circuit layer on a side of the first glass substrate; and bonding and connecting a radio frequency processing chip on a side of the circuit layer away from the first glass substrate.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a planar schematic diagram of an exemplary sensor consistent with various disclosed embodiments of the present disclosure;

FIG. 2 illustrates a cross-sectional view along an A-A′ direction of the sensor in FIG. 1, consistent with various disclosed embodiments of the present disclosure;

FIG. 3 illustrates a planar schematic diagram of another exemplary sensor consistent with various disclosed embodiments of the present disclosure;

FIG. 4 illustrates a cross-sectional view along a B-B′ direction of the sensor in FIG. 3, consistent with various disclosed embodiments of the present disclosure;

FIG. 5 illustrates a cross-sectional view along a C-C′ direction of the sensor in FIG. 3, consistent with various disclosed embodiments of the present disclosure;

FIG. 6 illustrates a planar schematic diagram of another exemplary sensor consistent with various disclosed embodiments of the present disclosure;

FIG. 7 illustrates a cross-sectional view along a D-D′ direction of the sensor in FIG. 6, consistent with various disclosed embodiments of the present disclosure;

FIG. 8 illustrates a cross-sectional view along an E-E′ direction of the sensor in FIG. 6, consistent with various disclosed embodiments of the present disclosure;

FIG. 9 illustrates a planar schematic diagram of another exemplary sensor consistent with various disclosed embodiments of the present disclosure;

FIG. 10 illustrates a schematic structure of the sensor in FIG. 9, consistent with various disclosed embodiments of the present disclosure;

FIG. 11 illustrates another schematic structure of the sensor in FIG. 9, consistent with various disclosed embodiments of the present disclosure;

FIG. 12 illustrates a flowchart of an exemplary fabrication method of a sensor consistent with various disclosed embodiments of the present disclosure;

FIG. 13 illustrates a flowchart of another exemplary fabrication method of a sensor consistent with various disclosed embodiments of the present disclosure;

FIG. 14 and FIG. 15 illustrates a structure schematic diagram corresponding to different steps in the fabrication method of a sensor in FIG. 13, consistent with various disclosed embodiments of the present disclosure;

FIG. 16 illustrates another flowchart of an exemplary fabrication method of a sensor consistent with various disclosed embodiments of the present disclosure;

FIG. 17 and FIG. 18 illustrate structure schematic diagrams corresponding to different steps in the fabrication method of a sensor in FIG. 16, consistent with various disclosed embodiments of the present disclosure;

FIG. 19 illustrates a flowchart of another exemplary fabrication method of a sensor consistent with various disclosed embodiments of the present disclosure;

FIG. 20 illustrates a flowchart of another exemplary fabrication method of a sensor consistent with various disclosed embodiments of the present disclosure; and

FIG. 21 illustrates a planar schematic diagram of another exemplary sensor consistent with various disclosed embodiments of the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like portions, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be exaggerated. Besides, those schematic diagrams are merely examples, and not intended to limit the scope of the disclosure. Furthermore, a three-dimensional (3D) size including length, width, and depth should be considered during practical fabrication.

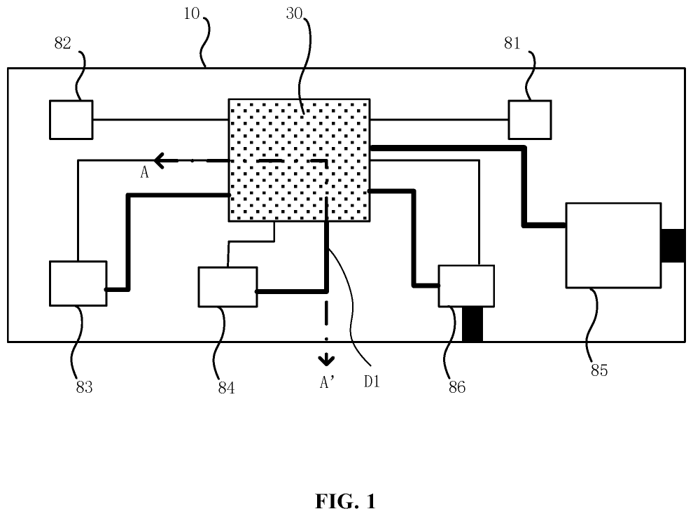

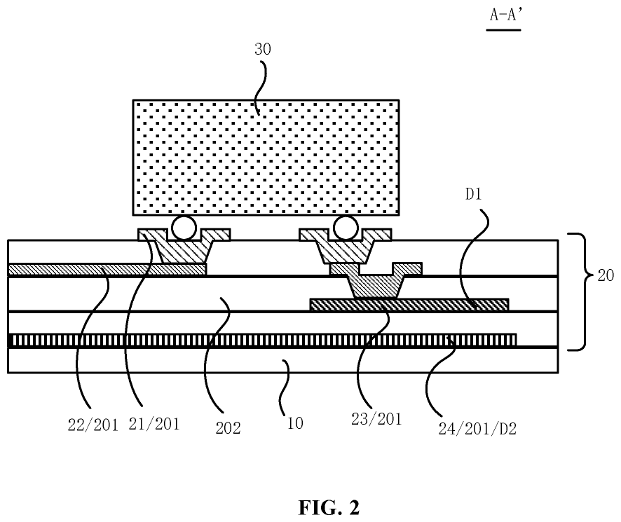

The present disclosure provides a sensor. FIG. 1 illustrates a planar structure of a sensor provided by one embodiment of the present disclosure, and FIG. 2 illustrates a cross-sectional view along an A-A′ direction of the sensor in FIG. 1. As shown in FIG. 1 and FIG. 2, one embodiment of the present disclosure provides a sensor. The sensor may include a first glass substrate 10 and a circuit layer 20 on a side of the first glass substrate 10.

The sensor may further include a radio frequency processing chip 30. The radio frequency processing chip 30 may be disposed on a side of the circuit layer 20 away from the first glass substrate 10. The radio frequency processing chip 30 may be bonded on the first glass substrate 10.

In existing technologies, the radio frequency processing chip is usually bonded on a printed circuit board, and the printed circuit board is usually made of a Rogers or FR4 board. A minimum line width of wirings set on the printed circuit board can only be set to about 30˜50 μm. Correspondingly, the roughness of film layers for wirings provided on the printed circuit board is in the order of micrometer. That is, the film roughness of each wiring layer on the printed circuit board is relatively large. Since the radio frequency signal is more sensitive to the film roughness of each wiring layer, when the radio frequency processing chip is bonded to the printed circuit board, the radiation loss of the radio frequency signal is large and the radiation efficiency is low. Especially when transmitting 77 GHZ high-frequency signals, the high-frequency signals are more sensitive to the roughness of the film layer of each wiring layer, so the radiation loss of the high-frequency signals is larger when the structure of bonding the radio frequency processing chip on the printed circuit board is adopted.

In the present embodiment of the present disclosure, the radio frequency processing chip 30 may be bonded on the first glass substrate 10, and the circuit layer 20 may be fabricated on the first glass substrate 10 by a panel process with high flatness and low film layer roughness. That is, the minimum line width of wirings in the circuit layer 20 on the first glass substrate 10 may be set smaller. For example, the exemplary minimum line width of the wirings in the circuit layer 20 on the first glass substrate 10 may be set to about 5 μm, such that the film layer roughness of the wirings provided on the first glass substrate 10 may be on the order of tens of nm and the film roughness of each wiring layer in the circuit layer 20 may be small. Correspondingly, when the radio frequency processing chip 30 is bonded to the first glass substrate 10, the radiation loss of the radio frequency signals may be effectively reduced and the detection accuracy may be improved. Exemplarily, when the structure of bonding the radio frequency processing chip 30 to the first glass substrate 10 is adopted, the radiation loss of the 24 GHz or 77 GHz high frequency signals because of the roughness of the film layer may be reduced.

As shown in FIG. 1 and FIG. 2, in some optional embodiments, the circuit layer 20 may include a plurality of metal layers 201 and a plurality of insulating layers 202. One of the plurality of insulating layers 202 may be disposed between two adjacent metal layers 201 of the plurality of metal layers 201. The plurality of insulating layers 202 may be made of a material including polyimide, and the plurality of metal layers 201 may be made of a material including copper, silver, gold, or a combination thereof.

For example, in one embodiment, the wiring layer 20 may include four metal layers 201, which are respectively a fourth metal layer 24, a third metal layer 23, a second metal layer 22 and a first metal layer 21. Insulating layers 202 may be disposed between the fourth metal layer 24 and the third metal layer 23, between the third metal layer 23 and the second metal layer 22, and between the second metal layer 22 and the first metal layer 21.

The insulating layers 202 in the circuit layer 20 may be made of polyimide, and the thickness of the insulating layers 202 made of polyimide may be set thicker, therefore reducing signal loss. Exemplarily, the insulating layers 202 made of polyimide may have a thickness of 15 μm.

The metal layers 201 may be made of copper, silver, gold, or a combination thereof. Copper, silver and gold are all low resistance materials, and the metal layers 201 made of copper, silver, gold, or a combination thereof may be beneficial to reducing signal loss.

In some other embodiments, the insulating layers 202 in the circuit layer 20 may also be made of other materials that are able to form a thicker insulating layer, and the metal layers 201 may also be made of other low-resistance materials. The present disclosure has no limit on this.

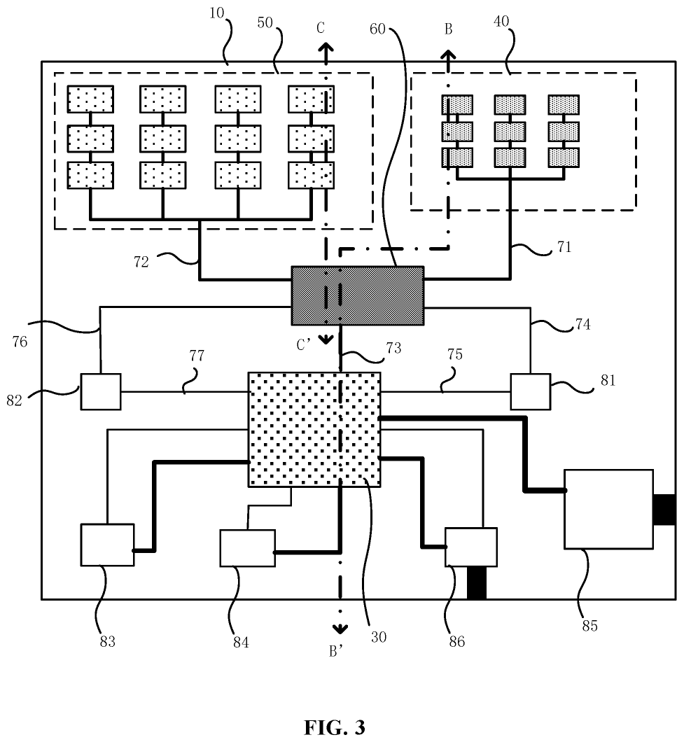

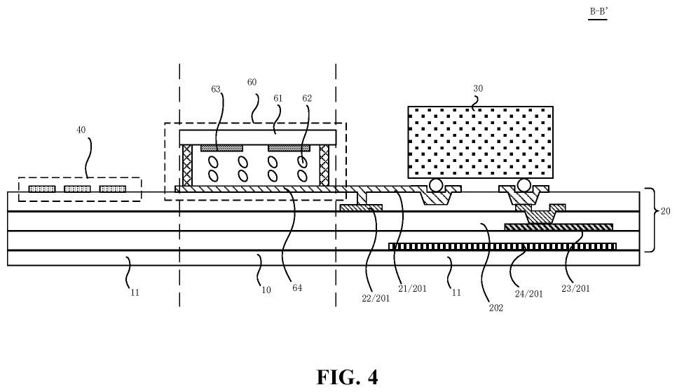

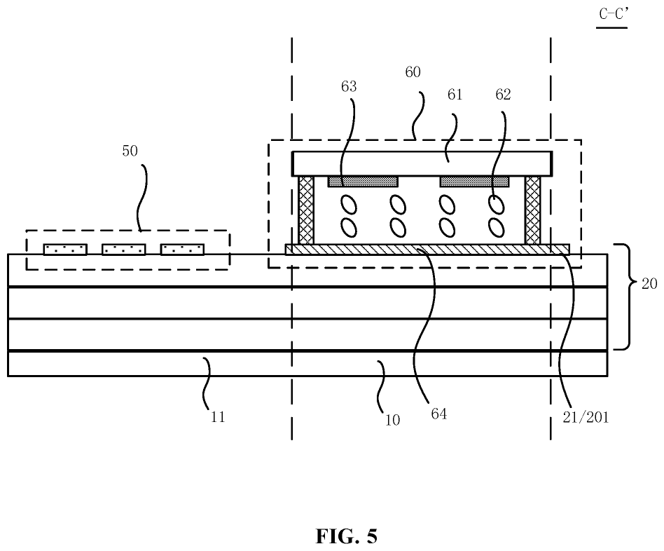

FIG. 3 illustrates a planar structure of another sensor provided by one embodiment of the present disclosure, FIG. 4 illustrates a cross-sectional view along a B-B′ direction of the sensor in FIG. 3, and FIG. 5 illustrates a cross-sectional view along a C-C′ direction of the sensor in FIG. 3. As shown in FIG. 3 to FIG. 5, the sensor may further include a transmitting antenna array 40, a receiving antenna array 50, and a phase shifter 60. Signals transmitted by the radio frequency processing chip 30 may be transmitted through the transmitting antenna array 40, and signals reflected by obstacles may be received through the receiving antenna array 50 and transmitted to the radio frequency processing chip 30. The sensor may be also provided with the phase shifter 60. The sensor may adjust the maximum gain direction of the signals emitted by the radio frequency processing chip 30 through the cooperation of the phase shifter 60 and the radio frequency processing chip 30, to realize multi-directional scanning of the sensor and tracking/detection of targets.

In existing technologies, ranges covered by a single sensor or multiple sensors have dead angles and it is impossible to realize all-round detection. A multi-sensor layout, or CMOS radio frequency integrated chip phase-shift scanning is adopted. But the dynamic power consumption is relatively high, and the relative cost is relatively high.

In the present disclosure, the cooperation of the phase shifter 60 and the radio frequency processing chip 30 may realize the improvement of the detection coverage of the sensor, which may be beneficial to reduce the number of deployed sensors. And the phase shifter 60 may be a liquid crystal phase shifter, that is, a low-cost liquid crystal phase shifter may be used in the present disclosure to replace a traditional expensive CMOS radio frequency integrated chip. The liquid crystal phase shifter may be able to realize the electronic scanning function and perform viewing angle compensation. The scanning may use a specific gray scale, such that the driving may be easier to realize and the response time may not need to be too high, which is beneficial to reduce the cost.

For description purposes only, the embodiment in FIG. 3 where the transmitting antenna array 40 is a series-fed 1×3 antenna array and the receiving antenna array 50 is a series-fed 1×4 antenna array is used as an example to illustrate the present disclosure, and does not limit the scope of the present disclosure. In some other embodiments, the transmitting antenna array 40 and the receiving antenna array 50 may be any other suitable array structures.

The transmitting antenna array 40, the receiving antenna array 50 and the phase shifter 60 may be all disposed on the side of the circuit layer 20 away from the first glass substrate 10. That is, in the sensor, the transmitting antenna array 40, the receiving antenna array 50 and the phase shifter 60 may be integrated into the first glass substrate 10, to improve the integration level of the sensor.

As shown in FIG. 3 to FIG. 5, in some optional embodiments, the phase shifter 60 may include a second glass substrate 61 corresponding to the first glass substrate 10, and a liquid crystal layer 62 between the first glass substrate 10 and the second glass substrate 61.

The first glass substrate 10 may include an extension portion 11. Along a direction perpendicular to the plane where the first glass substrate 10 is located, the extension portion 11 may not overlap with the second glass substrate 61.

The transmitting antenna array 40, the receiving antenna array 50 and the radio frequency processing chip 30 may be disposed on the side of the circuit layer 20 away from the extension portion 11.

Both the transmitting antenna array 40 and the receiving antenna array 50 may be electrically connected to the phase shifter 60, and the phase shifter 60 may be electrically connected to the radio frequency processing chip 30.

In the sensor, a portion of the first glass substrate 10 corresponding to the second glass substrate 61 may be arranged opposite to the second glass substrate 61, and the liquid crystal layer 62 may be disposed between the portion of the first glass substrate 10 corresponding to the second glass substrate 61 and the second glass substrate 61, such that the phase shifter 60 is formed on the first glass substrate 10. Further, the first glass substrate 10 may include the extension portion 11 that does not overlap with the second glass substrate 61 along the direction perpendicular to the plane where the first glass substrate 10 is located. The transmitting antenna array 40, the receiving antenna array 50 and the radio frequency processing chip 30 may be disposed on the side of the circuit layer 20 away from the extension portion 11. Therefore, the transmitting antenna array 40, the receiving antenna array 50 and the radio frequency processing chip 30 may be integrated on the first glass substrate 10. By integrating the transmitting antenna array 40, the receiving antenna array 50, the phase shifter 60, and the radio frequency processing chip 30 into the first glass substrate 10, the integration degree of the sensor may be improved.

Also, the transmitting antenna array 40, the receiving antenna array 50 and the radio frequency processing chip 30 may be disposed on the side of the circuit layer 20 away from the extension portion 11. Therefore, the transmitting signal provided by the radio frequency processing chip 30 may be directly fed back to the transmitting antenna array 40 after being adjusted by the phase shifter 60, and the signal received by the receiving antenna array 50 may be directly fed back to the radio frequency processing chip 30 after the phase shifter 60 adjusts the phase. The feeding gain may be high, which is beneficial to improve the detection accuracy.

As shown in FIG. 3 to FIG. 5, in some embodiments, the phase shifter 60 may further include a first electrode 63 and a second electrode 64. The first electrode 63 may be located on a side of the second glass substrate 61 close to the first glass substrate 10. The transmitting antenna array 40 may be electrically connected to the second electrode 64 through a first wiring 71, the receiving antenna array 50 may be electrically connected to the second electrode 64 through a second wiring 72, and the second electrode 64 may be electrically connected to the radio frequency processing chip 30 through a third wiring 73.

The circuit layer 20 may include a first metal layer 21 on the side of the circuit layer 20 away from the first glass substrate 10.

The transmitting antenna array 40, the receiving antenna array 50, the first wiring 71, the second wiring 72, the third wiring 73, and the second electrode 64 may be all disposed in the first metal layer 21.

In the present embodiment, the phase shifter 60 may further include first electrode 63 and the second electrode 64. The first electrode 63 may be grounded. When transmitting signals, by applying voltage to the first electrode 63 and the second electrode 64 to control the strength of the electric field formed between the first electrode 63 and the second electrode 64, the deflection angle of the liquid crystal molecules in the liquid crystal layer 62 in the corresponding space may be adjusted to adjust the dielectric strength of the liquid crystal layer 62. Correspondingly, the phase shift of the signal may be realized in the liquid crystal layer 62, achieving the effect of changing the phase of the signal.

The transmitting antenna array 40 may be electrically connected to the second electrode 64 through the first wiring 71, and the second electrode 64 may be electrically connected to the radio frequency processing chip 30 through the third wiring 73. Therefore, the transmitting signal provided by the radio frequency processing chip 30 may be directly fed back to the transmitting antenna array 40 after being adjusted by the phase shifter 60. The receiving antenna array 50 may be electrically connected to the second electrode 64 through the second wiring 72, and the second electrode 64 may be electrically connected to the radio frequency processing chip 30 through the third wiring 73. Therefore, the signal received by the receiving antenna array 50 may be directly fed back to the radio frequency processing chip 30 after the phase shifter 60 adjusts the phase.

The circuit layer 20 may include the first metal layer 21 on the side of the circuit layer 20 away from the first glass substrate 10. The transmitting antenna array 40, the receiving antenna array 50, the first wiring 71, the second wiring 72, the third wiring 73, and the second electrode 64 may be all disposed in the first metal layer 21. The transmitting antenna array 40 may be electrically connected to the second electrode 64 through the first wiring 71, the receiving antenna array 50 may be electrically connected to the second electrode 64 through the second wiring 72, and the second electrode 64 may be electrically connected to the radio frequency processing chip 30 through the third wiring 73. The connection may be simple.

As shown in FIG. 3 to FIG. 5, in some embodiments, the sensor may further include a transmitting antenna power amplifier 81 and a low noise amplifier 82. The transmitting antenna power amplifier 81 and the low noise amplifier 82 may be disposed on the side of the circuit layer 20 away from the extension portion 11.

The transmitting antenna power amplifier 81 may be electrically connected to the second electrode through a fourth wiring 74, and may be electrically connected to the radio frequency processing chip 30 through a fifth wiring 75.

The low noise amplifier 82 may be electrically connected to the second electrode 64 through a sixth wiring 76 and may be electrically connected to the radio frequency processing chip 30 through a seventh wiring 77.

The circuit layer 20 may further include a second metal layer 22 between the first metal layer 21 and the first glass substrate 10.

The fourth wiring 74, the fifth wiring 75, the sixth wiring, and the seventh wiring 77 may be all located in the second metal layer 22.

In the present embodiment, the sensor may further include the transmitting antenna power amplifier 81 and the low-noise amplifier 82. The transmitting antenna power amplifier 81 and the low noise amplifier 82 may be disposed on the side of the circuit layer 20 away from the extension portion 11. That is, the transmitting antenna power amplifier 81 and the low noise amplifier 82 may be also integrated into the first glass substrate 10, to further improve the integration level of the sensor.

The transmitting antenna power amplifier 81 may be electrically connected to the second electrode through the fourth wiring 74, and may be electrically connected to the radio frequency processing chip 30 through the fifth wiring 75, to amplify the signal transmitted by the radio frequency processing chip 30.

The low noise amplifier 82 may be electrically connected to the second electrode 64 through the sixth wiring 76 and may be electrically connected to the radio frequency processing chip 30 through the seventh wiring 77, to improve the quality of the signal received by the radio frequency processing chip 30.

The fourth wiring 74, the fifth wiring 75, the sixth wiring, and the seventh wiring 77 may be all located in the second metal layer 22. Therefore, the electrical connection of the transmitting antenna power amplifier 81, the low noise amplifier 82 and the radio frequency processing chip 30 may be realized, the interference of them on the first wiring 71, the second wiring 72 and the third wiring 73 may be reduced, and the wiring difficulty may be reduced, at the same time.

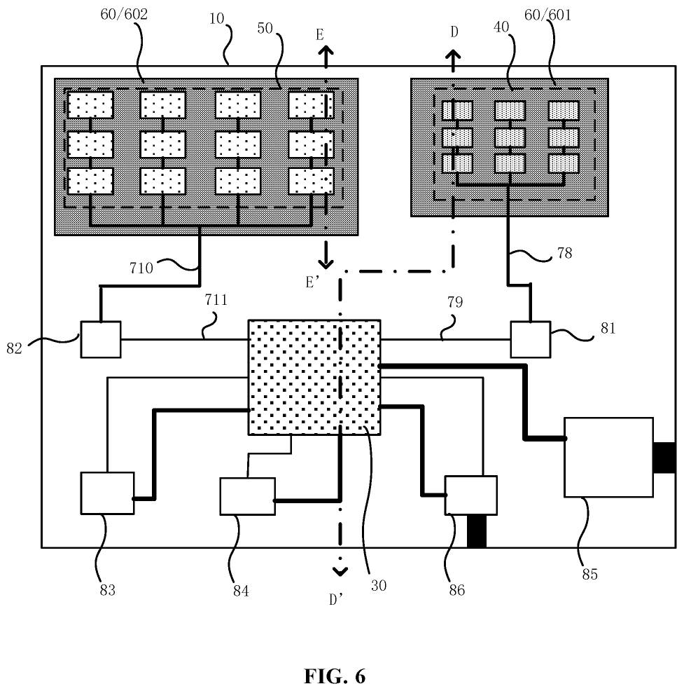

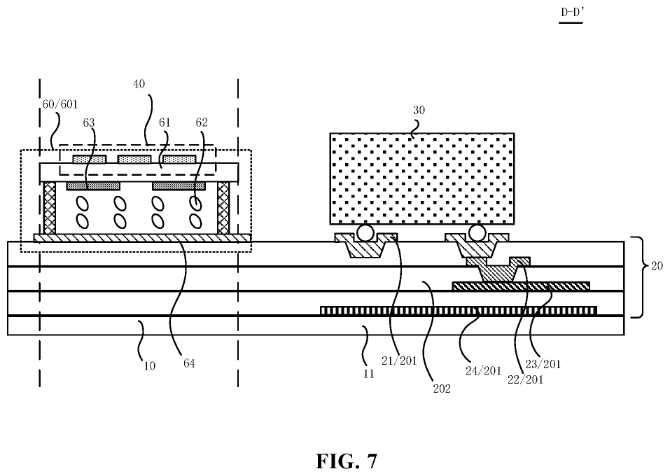

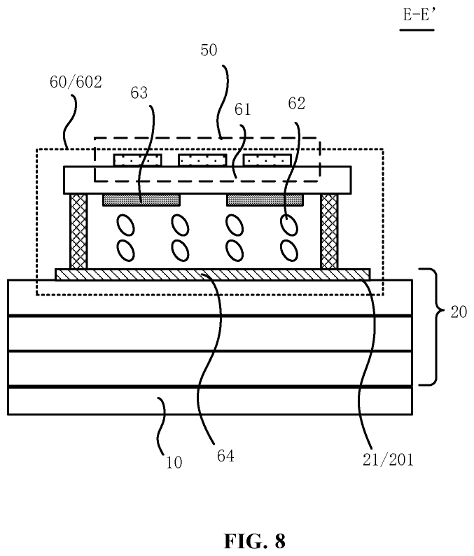

FIG. 6 illustrates a planar structure of another sensor provided by one embodiment of the present disclosure, FIG. 7 illustrates a cross-sectional view along a D-D′ direction of the sensor in FIG. 6, and FIG. 8 illustrates a cross-sectional view along an E-E′ direction of the sensor in FIG. 6. As shown in FIG. 6 to FIG. 8, in some optional embodiments, the phase shifter 60 may include a second glass substrate 61 corresponding to the first glass substrate 10, and a liquid crystal layer 62 between the first glass substrate 10 and the second glass substrate 61.

The first glass substrate 10 may include an extension portion 11. Along a direction perpendicular to the plane where the first glass substrate 10 is located, the extension portion 11 may not overlap with the second glass substrate 61.

The radio frequency processing chip 30 may be disposed on the side of the circuit layer 20 away from the extension portion 11.

The phase shifter 60 may include a first phase shifter 601 and a second phase shifter 602. The transmitting antenna array 40 may be disposed on a side of the second glass substrate 61 in the first phase shifter 601 away from the first glass substrate 10, and the receiving antenna array 50 may be disposed on a side of the second glass substrate 61 in the second phase shifter 602 away from the first glass substrate 10.

Both the transmitting antenna array 40 and the receiving antenna array 50 may be electrically connected to the radio frequency processing chip 30.

In the sensor, a portion of the first glass substrate 10 corresponding to the second glass substrate 61 may be arranged opposite to the second glass substrate 61, and the liquid crystal layer 62 may be disposed between the portion of the first glass substrate 10 corresponding to the second glass substrate 61 and the second glass substrate 61, such that the phase shifter 60 is formed on the first glass substrate 10. Further, the first glass substrate 10 may include the extension portion 11 that does not overlap with the second glass substrate 61 along the direction perpendicular to the plane where the first glass substrate 10 is located. The radio frequency processing chip 30 may be disposed on the side of the circuit layer 20 away from the extension portion 11. Therefore, the radio frequency processing chip 30 may be integrated on the first glass substrate 10. By integrating the radio frequency processing chip 30 into the first glass substrate 10, the integration degree of the sensor may be improved.

The phase shifter 60 may include the first phase shifter 601 and the second phase shifter 602. The transmitting antenna array 40 may be disposed on the side of the second glass substrate 61 in the first phase shifter 601 away from the first glass substrate 10, and the receiving antenna array 50 may be disposed on the side of the second glass substrate 61 in the second phase shifter 602 away from the first glass substrate 10. Therefore, the transmitting antenna array 40 and the receiving antenna array 50 may be also integrated into the first glass substrate 10, and the integration degree of the sensor may be improved. Also, the transmitting antenna array 40 may be disposed on the side of the second glass substrate 61 in the first phase shifter 601 away from the first glass substrate 10, such that the second glass substrate 61 in the first phase shifter 601 may be multiplexed to integrate the transmitting antenna array 40. The receiving antenna array 50 may be disposed on the side of the second glass substrate 61 in the second phase shifter 602 away from the first glass substrate 10, such that the second glass substrate 61 in the second phase shifter 602 may be multiplexed to integrate the receiving antenna array 50. The volume of the sensor may be reduced.

As shown in FIG. 6 to FIG. 8, in some embodiments, the phase shifter 60 may further include a first electrode 63 and a second electrode 64. The first electrode 63 may be located on a side of the second glass substrate 61 close to the first glass substrate 10.

The circuit layer 20 may include a first metal layer 21 on the side of the circuit layer 20 away from the first glass substrate 10.

The second electrode 64 may be disposed in the first metal layer 21.

In the present embodiment, the phase shifter 60 may further include first electrode 63 and the second electrode 64. The first electrode 63 may be located on the side of the second glass substrate 61 close to the first glass substrate 10. The second electrode 64 may be disposed in the first metal layer 21. The second electrode 64 may be grounded. When transmitting signals, by applying voltage to the first electrode 63 and the second electrode 64 to control the strength of the electric field formed between the first electrode 63 and the second electrode 64, the deflection angle of the liquid crystal molecules in the liquid crystal layer 62 in the corresponding space may be adjusted to adjust the dielectric strength of the liquid crystal layer 62. Correspondingly, the phase shift of the signal may be realized in the liquid crystal layer 62, achieving the effect of changing the phase of the signal.

Both the transmitting antenna array 40 and the receiving antenna array 50 may be electrically connected to the radio frequency processing chip 30. The signal transmitted by the transmitting antenna array 40 may adopt the coupling feeding mode to realize the phase shift of the signal, and the signal to be received may be transmitted to the receiving antenna array 50 after phase shift adopting the coupling feeding mode to realize the phase shift of the signal.

As shown in FIG. 6 to FIG. 8, in some embodiments, the sensor may further include a transmitting antenna power amplifier 81 and a low noise amplifier 82. The transmitting antenna power amplifier 81 and the low noise amplifier 82 may be disposed on the side of the circuit layer 20 away from the extension portion 11.

The transmitting antenna power amplifier 81 may be electrically connected to the transmitting antenna array 40 through an eighth wiring 78, and may be electrically connected to the radio frequency processing chip 30 through a ninth wiring 79.

The low noise amplifier 82 may be electrically connected to the receiving antenna array 50 through a tenth wiring 710 and may be electrically connected to the radio frequency processing chip 30 through an eleventh wiring 711.

The circuit layer 20 may further include a second metal layer 22 between the first metal layer 21 and the first glass substrate 10.

The eighth wiring 78 and the tenth wiring 710 may be disposed in the first metal layer 21.

The ninth wiring 79 and the eleventh wiring 711 may be located in the second metal layer 22.

In the present embodiment, the sensor may further include the transmitting antenna power amplifier 81 and the low-noise amplifier 82. The transmitting antenna power amplifier 81 and the low noise amplifier 82 may be disposed on the side of the circuit layer 20 away from the extension portion 11. That is, the transmitting antenna power amplifier 81 and the low noise amplifier 82 may be also integrated into the first glass substrate 10, to further improve the integration level of the sensor.

The transmitting antenna power amplifier 81 may be electrically connected to the transmitting antenna array 40 through the eighth wiring 78, and may be electrically connected to the radio frequency processing chip 30 through the ninth wiring 79, to amplify the signal transmitted by the radio frequency processing chip 30.

The low noise amplifier 82 may be electrically connected to the receiving antenna array 50 through the tenth wiring 710 and may be electrically connected to the radio frequency processing chip 30 through the eleventh wiring 711, to improve the quality of the signal received by the radio frequency processing chip 30.

The eighth wiring 78 and the tenth wiring 710 may be disposed in the first metal layer 21. The ninth wiring 79 and the eleventh wiring 711 may be located in the second metal layer 22. Therefore, the electrical connection of the transmitting antenna power amplifier 81, the low noise amplifier 82 and the radio frequency processing chip 30 may be realized, the interference between wirings may be reduced, and the wiring difficulty may be reduced, at the same time.

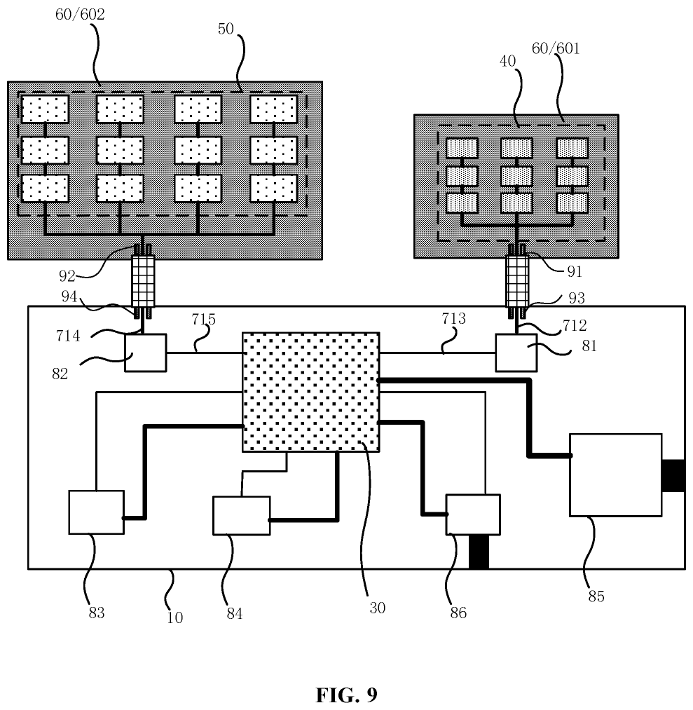

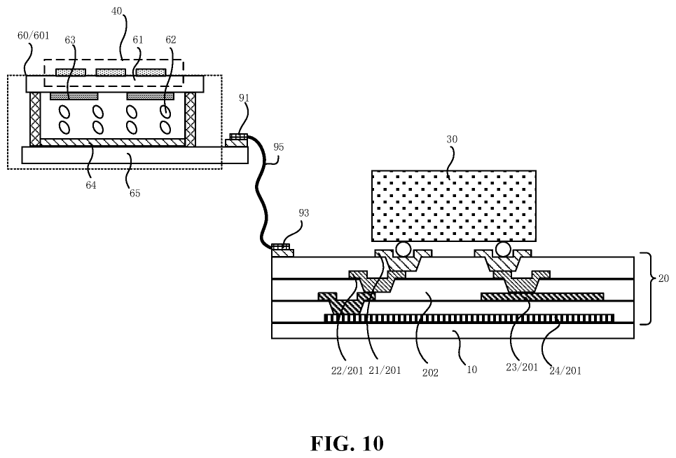

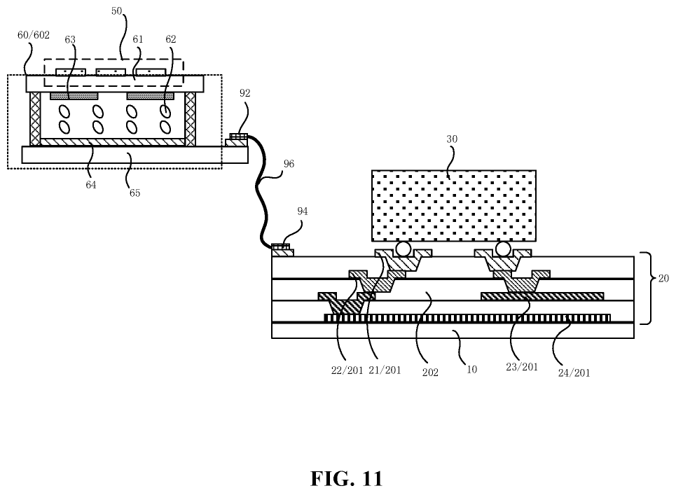

As shown in FIG. 9 which illustrates a planar schematic diagram of another sensor, FIG. 10 illustrating a structure of the sensor in FIG. 9, and FIG. 11 illustrating another structure of the senor in FIG. 9, in some other embodiments, the sensor may further include a transmitting antenna array 40, a receiving antenna array 50, and a phase shifter 60.

The phase shifter 60 may include a second glass substrate 61 and a third glass substrate 65 oppositely arranged, a liquid crystal layer 62 between the second glass substrate 61 and the third glass substrate 65, a first electrode 63, and a second electrode 64. The first electrode 63 may be disposed on a side of the second glass substrate 61 close to the third glass substrate 65, and the second electrode 64 may be disposed on a side of the third glass substrate 65 close to the second glass substrate 61.

The phase shifter 60 may further include a first phase shifter 601 and a second phase shifter 602. The transmitting antenna array 40 may be located on a side of the second glass substrate 61 in the first phase shifter 601 away from the third glass substrate 65. The receiving antenna array 50 may be located on a side of the second glass substrate 61 in the second phase shifter 602 away from the third glass substrate 65.

In the present embodiment, the second glass substrate 61 and the third glass substrate 65 may be disposed oppositely to each other, and the liquid crystal layer 62 may be disposed between the second glass substrate 61 and the third glass substrate 65. That is, the phase shifter 60 and the radio frequency processing chip 30 may be disposed on different glass substrates. The phase shifter 60 and the radio frequency processing chip 30 may be mutually independent structures, and may be connected or replaced more flexibly according to usage requirements. Further, the manufacturing of the phase shifter 60 and the bonding of the radio frequency processing chip 30 may be manufactured separately, which is beneficial to reduce the difficulty of the process.

The phase shifter 60 may further include the first phase shifter 601 and the second phase shifter 602. The transmitting antenna array 40 may be located on the side of the second glass substrate 61 in the first phase shifter 601 away from the third glass substrate 65. The receiving antenna array 50 may be located on the side of the second glass substrate 61 in the second phase shifter 602 away from the third glass substrate 65. The second glass substrate 61 in the first phase shifter 601 may be multiplexed to integrate the transmitting antenna array 40, and the second glass substrate 61 in the second phase shifter 602 may be multiplexed to integrate the receiving antenna array 50. The volume of the sensor may be reduced.

The third glass substrate 65 in the first phase shifter 601 and the third glass substrate 65 in the second phase shifter 602 may be the same glass substrate. That is, the first phase shifter 601 and the second phase shifter 602 may be integrated into the same glass substrate, which is beneficial to improve the integration level. The second glass substrate 61 in the first phase shifter 601 and the second glass substrate 61 in the second phase shifter 602 may be the same glass substrate or different glass substrates. In some other embodiments, the third glass substrate 65 in the first phase shifter 601 and the third glass substrate 65 in the second phase shifter 602 may also be different glass substrates, that is, the first phase shifter 601 and the second phase shifter 602 may be structures independent from each other, and may be connected or replaced more flexibly according to the use requirements. The first phase shifter 601 and the second phase shifter 602 may be manufactured separately, and the manufacturing process may be more mature, which is beneficial to reducing the difficulty of the process. At this time, the second glass substrate 61 in the first phase shifter 601 and the second glass substrate 61 in the second phase shifter 602 may also be different glass substrates.

As shown in FIG. 9 to FIG. 11, in some optional embodiments, a first radio frequency connector 91 may be provided on the third glass substrate 65 in the first phase shifter 601, and the first radio frequency connector 91 may be electrically connected to the transmitting antenna array 40.

A second radio frequency connector 92 may be provided on the third glass substrate 65 in the second phase shifter 602, and the second radio frequency connector 92 may be electrically connected to the receiving antenna array 50.

A third radio frequency connector 93 and a fourth radio frequency connector 93 may be provided on the side of the circuit layer 20 away from the first glass substrate 10. The first radio frequency connector 91 may be electrically connected to the third radio frequency connector 93 through a first coaxial line 95, and the second radio frequency connector 92 may be electrically connected to the fourth radio frequency connector 93 through a second coaxial line 96.

In the present embodiment, the phase shifter 60 and the radio frequency processing chip 30 in the sensor may be mutually independent structures. The first radio frequency connector 91 may be disposed on the third glass substrate 65 in the first phase shifter 601, and the first radio frequency connector 91 may be electrically connected to the transmitting antenna array 40. The first radio frequency connector 91 may be electrically connected to the third radio frequency connector 93 through the first coaxial line 95, to transmit the signal between the radio frequency processing chip 30 and the transmitting antenna array 40 on the side of the second glass substrate 61 in the first phase shifter 601. Similarly, the second radio frequency connector 92 may be provided on the third glass substrate 65 in the second phase shifter 602, and the second radio frequency connector 92 may be electrically connected to the receiving antenna array 50. The second radio frequency connector 92 may be electrically connected to the fourth radio frequency connector 93 through a second coaxial line 96, to transmit the signal between the radio frequency processing chip 30 and the receiving antenna array 50 located on the side of the second glass substrate 61 in the first phase shifter 601.

As shown in FIG. 9 to FIG. 11, in some embodiments, the sensor may further include a transmitting antenna power amplifier 81 and a low noise amplifier 82. The transmitting antenna power amplifier 81 and the low noise amplifier 82 may be disposed on the side of the circuit layer 20 away from the first glass substrate 10.

The transmitting antenna power amplifier 81 may be electrically connected to the third radio frequency connector 93 through a twelfth wiring 712, and may be electrically connected to the radio frequency processing chip 30 through a thirteenth wiring 713.

The low noise amplifier 82 may be electrically connected to the fourth radio frequency connector 94 through a fourteenth wiring 714 and may be electrically connected to the radio frequency processing chip 30 through a fifteenth wiring 715.

The circuit layer 20 may further include a first metal layer 21 and a second metal layer 22 between the first metal layer 21 and the first glass substrate 10.

The twelfth wiring 712 and the fourteenth wiring 714 may be disposed in the first metal layer 21.

The thirteenth wiring 713 and the fifteenth wiring 715 may be located in the second metal layer 22.

In the present embodiment, the sensor may further include the transmitting antenna power amplifier 81 and the low-noise amplifier 82. The transmitting antenna power amplifier 81 and the low noise amplifier 82 may be disposed on the side of the circuit layer 20 away from the extension portion 11. That is, the transmitting antenna power amplifier 81 and the low noise amplifier 82 may be also integrated into the first glass substrate 10, to further improve the integration level of the sensor.

The transmitting antenna power amplifier 81 may be electrically connected to the third radio frequency connector 93 through the twelfth wiring 712 and may be electrically connected to the radio frequency processing chip 30 through the thirteenth wiring 713, to amplify the signal transmitted by the radio frequency processing chip 30.

The low noise amplifier 82 may be electrically connected to the fourth radio frequency connector 94 through the fourteenth wiring 714 and may be electrically connected to the radio frequency processing chip 30 through the fifteenth wiring 715, to improve the quality of the signal received by the radio frequency processing chip 30.

The twelfth wiring 712 and the fourteenth wiring 714 may be disposed in the first metal layer 21. The thirteenth wiring 713 and the fifteenth wiring 715 may be located in the second metal layer 22. Therefore, the electrical connection of the transmitting antenna power amplifier 81, the low noise amplifier 82 and the radio frequency processing chip 30 may be realized, the interference between wirings may be reduced, and the wiring difficulty may be reduced, at the same time.

As shown in FIG. 1 and FIG. 2, in some optional embodiments, the sensor may further include a resistance module 83, a capacitive device module 84, a power supply module 85, and an I/O chip 86. The resistance module 83, the capacitive device module 84, the power supply module 85 and the I/O chip 86 may be all electrically connected to the radio frequency processing chip 30. The I/O chip 86 may be used for post-processing the transmitted signal and the received signal. Optionally, the resistance module 83, the capacitive device module 84, the power module 85 and the I/O chip 86 may all be arranged on the first glass substrate 10, which may be beneficial to improve the integration of the sensor.

For description purposes only, the embodiments shown in FIG. 1 and FIG. 2 are used as examples to illustrate the present disclosure, and do not limit the scope of the present disclosure. In various embodiments, the sensor may include other suitable components.

As shown in FIG. 1 and FIG. 2, in some optional embodiments, the circuit layer 20 may include a plurality of signal lines D1 and a plurality of ground lines D2. The plurality of signal lines D1 may be electrically connected to the radio frequency processing chip 30, and the plurality of signal lines D1 may be used for transmitting radio frequency signals. The wires connecting the resistance module 83, the capacitive device module 84, the I/O chip 86 and the radio frequency processing chip 30 may all be signal wires D1.

The vertical projections of one of the plurality of signal lines D1 on the first glass substrate 10 may be located within the vertical projection of a corresponding one of the plurality of grounding lines D2 on the first glass substrate 10, such that radio frequency signals are able to be transmitted on the plurality of signal lines D1. Optionally, the plurality of ground wires D2 may be disposed on the fourth metal layer 24. Of course, in other embodiments of the present disclosure, the plurality of ground wires D2 may also be disposed on other metal layers in the circuit layer 20, and the present disclosure has no specific limit on this.

Also, as shown in FIG. 6, the wirings connecting the transmitting antenna power amplifier 81, the low noise amplifier 82 and the radio frequency processing chip 30 may be also the signal lines, and the settings in the above-mentioned embodiments may also be used to realize the transmitting of radio frequency signals on the signal lines.

For description purposes only, the embodiment in FIG. 2 where one of the plurality of ground wires D2 is disposed between two corresponding signal wires D1 of the plurality of signal wires D1 is used as an example only to illustrate the present disclosure, and does not limit the scope of the present disclosure. In some other embodiments, one of the plurality of ground wires D2 may be disposed at a side of a corresponding signal wire D1 of the plurality of signal wires D1 away from the substrate plate 10.

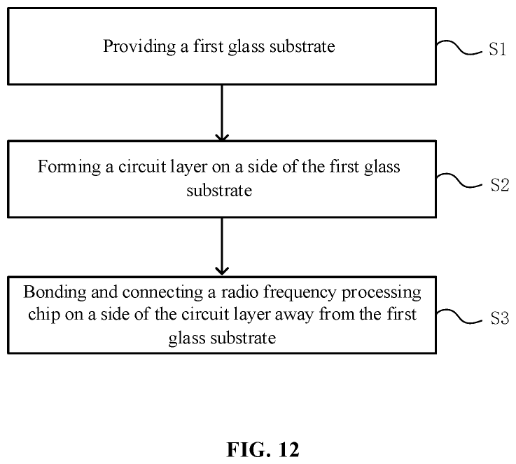

The present disclosure also provides a fabrication method of a sensor. FIG. 12 illustrates a flowchart of a fabrication method of a sensor consistent with various embodiments of the present disclosure. As shown in FIG. 1, FIG. 2, and FIG. 12, in one embodiment, the method may include:
S1: providing a first glass substrate;
S2: forming a circuit layer on a side of the first glass substrate; and
S3: bonding and connecting a radio frequency processing chip at a side of the circuit layer away from the first glass substrate.

By bonding the radio frequency processing chip at the side of the circuit layer away from the first glass substrate, the radio frequency processing chip may be bonded with the first glass substrate.

In existing technologies, the radio frequency processing chip is usually bonded on a printed circuit board, and the printed circuit board is usually made of a Rogers or FR4 board. A minimum line width of wirings set on the printed circuit board can only be set to about 30˜50 μm. Correspondingly, a roughness of film layers for wirings provided on the printed circuit board is in the order of micrometer. That is, the film roughness of each wiring layer on the printed circuit board is relatively large. Since the radio frequency signal is more sensitive to the film roughness of each wiring layer, when the radio frequency processing chip is bonded on the printed circuit board, the radiation loss of the radio frequency signal is large and the radiation efficiency is low. Especially when transmitting 77 GHZ high-frequency signals, the high-frequency signals are more sensitive to the roughness of the film layer of each wiring layer, so the radiation loss of the high-frequency signals is larger when the structure of bonding the radio frequency processing chip on the printed circuit board is adopted.

In the present embodiment of the present disclosure, the radio frequency processing chip 30 may be bonded on the first glass substrate 10, and the circuit layer 20 may be fabricated on the first glass substrate 10 by a panel process with high flatness and low film layer roughness. That is, the minimum line width of wirings in the circuit layer 20 on the first glass substrate 10 may be set smaller. For example, the exemplary minimum line width of the wirings in the circuit layer 20 on the first glass substrate 10 may be set to about 5 μm, such that the film layer roughness of the wirings provided on the first glass substrate 10 may be on the order of tens of nm and the film roughness of each wiring layer in the circuit layer 20 may be small. Correspondingly, when the radio frequency processing chip 30 is bonded to the first glass substrate 10, the radiation loss of the radio frequency signals may be effectively reduced and the detection accuracy may be improved.

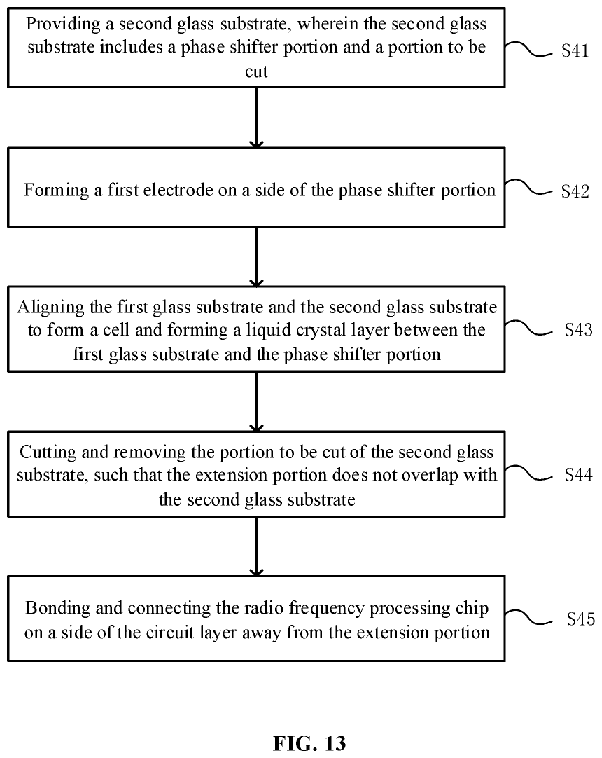

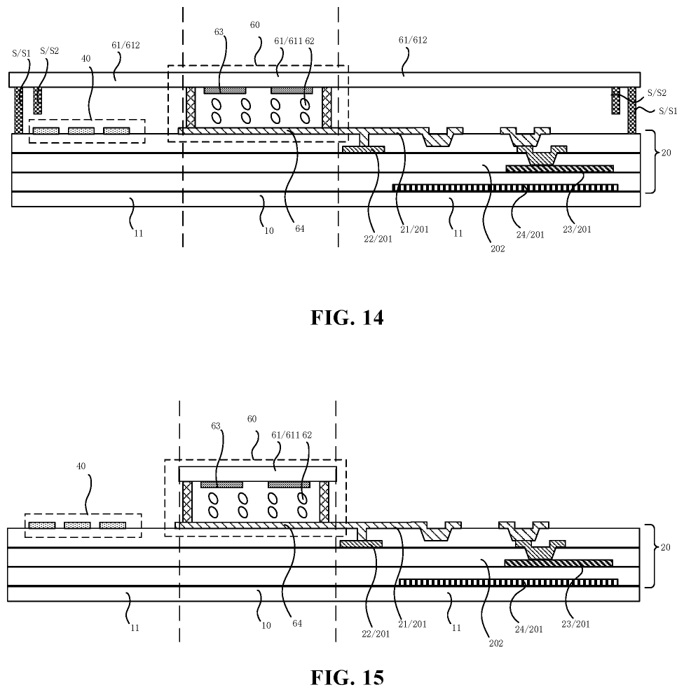

FIG. 13 illustrates a flowchart of another fabrication method of a sensor consistent with various embodiments of the present disclosure, and FIG. 14 and FIG. 15 illustrate structures corresponding to certain stages of the method in FIG. 13. As shown in FIG. 3 to FIG. 5, and FIG. 13 to FIG. 15, in some other embodiments, the circuit layer 20 may include a first metal layer 21 located on a side of the circuit layer 20 away from the first glass substrate 10. The first metal layer 21 may include a transmitting antenna array 40, a receiving antenna array 50, and a second electrode 64.

Correspondingly, the fabrication method of the sensor may further include S41 to S45.

In S41, a second glass substrate may be provided. The second glass substrate may include a phase shifter portion and a portion to be cut.

In S42, a first electrode may be formed at a side of the phase shifter portion.

In S43, the first glass substrate and the second glass substrate may be aligned to form a cell, such that the portion to be cut corresponds to an extension portion of the first glass substrate. A liquid crystal layer may be formed between the first glass substrate and the phase shifter portion. The first electrode may be located at the side of the phase shifter portion close to the first glass substrate, and the second electrode may be located on a side of the first glass substrate close to the phase shifter portion.

As shown in FIG. 14, after the first glass substrate 10 and the second glass substrate 61 are aligned to form the cell, the portion to be cut 612 may correspond to the extension portion 11 of the first glass substrate 10. The liquid crystal layer 62 may be formed between the first glass substrate 10 and the phase shifter portion 611. The first electrode may be located at the side of the phase shifter portion close to the first glass substrate, and the second electrode may be located on the side of the first glass substrate close to the phase shifter portion. Therefore, a phase shifter may be integrated into the first glass substrate 10.

In S44, the portion to be cut of the second glass substrate may be cut and removed, such that the extension portion does not overlap with the second glass substrate along a direction perpendicular to the plane where the first glass substrate is located.

As shown in FIG. 15, after the first glass substrate 10 and the second glass substrate 61 are aligned to form the cell, the portion to be cut of the second glass substrate 61 may be cut and removed and only the phase shifter portion 611 may be preserved in the second glass substrate 61. Along the direction perpendicular to the plane where the first glass substrate 10 is located, the extension portion 11 may not overlap with the second glass substrate 61, to facilitate subsequent integration of other components on the extension portion 11.

In S45, the radio frequency processing chip may be bonded and connected on the side of the circuit layer away from the extension portion.

In the present embodiment, a portion of the first glass substrate 10 corresponding to the second glass substrate 61 may be arranged opposite to the second glass substrate 61, and the liquid crystal layer 62 may be disposed between the portion of the first glass substrate 10 corresponding to the second glass substrate 61 and the second glass substrate 61, such that the phase shifter 60 is formed on the first glass substrate 10. Further, the first glass substrate 10 may include the extension portion 11 that does not overlap with the second glass substrate 61 along the direction perpendicular to the plane where the first glass substrate 10 is located. The transmitting antenna array 40, the receiving antenna array 50 and the radio frequency processing chip 30 may be disposed on the side of the circuit layer 20 away from the extension portion 11. Therefore, the transmitting antenna array 40, the receiving antenna array 50 and the radio frequency processing chip 30 may be integrated on the first glass substrate 10. By integrating the transmitting antenna array 40, the receiving antenna array 50, the phase shifter 60, and the radio frequency processing chip 30 into the first glass substrate 10, the integration degree of the sensor may be improved.

Also, the transmitting antenna array 40, the receiving antenna array 50 and the radio frequency processing chip 30 may be disposed on the side of the circuit layer 20 away from the extension portion 11. Therefore, the transmitting signal provided by the radio frequency processing chip 30 may be directly fed back to the transmitting antenna array 40 after being adjusted by the phase shifter 60, and the signal received by the receiving antenna array 50 may be directly fed back to the radio frequency processing chip 30 after the phase shifter 60 adjusts the phase. The feeding gain may be high, which is beneficial to improve the detection accuracy.

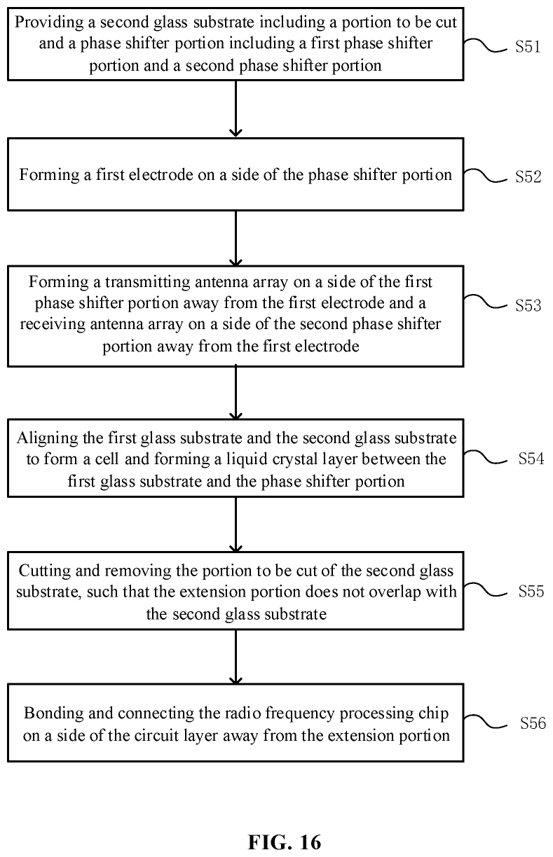

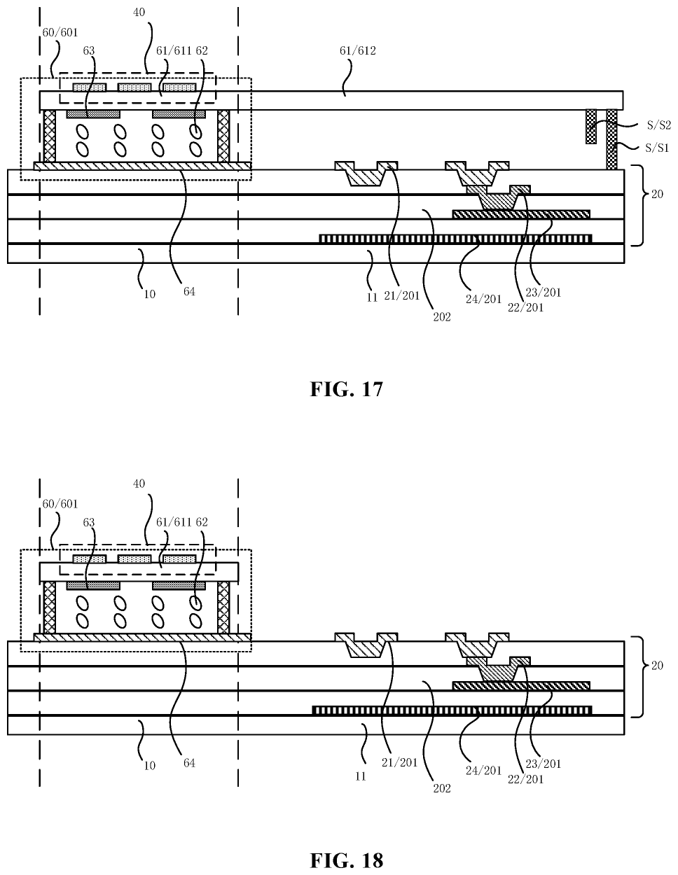

FIG. 16 illustrates a flowchart of another fabrication method of a sensor consistent with various embodiments of the present disclosure, and FIG. 17 and FIG. 18 illustrate structures corresponding to certain stages of the method in FIG. 16. As shown in FIG. 6 to FIG. 8 and FIG. 16, in some other embodiments, the circuit layer 20 may include a first metal layer 21 located on a side of the circuit layer 20 away from the first glass substrate 10. The first metal layer 21 may include a transmitting antenna array 40, a receiving antenna array 50, and a second electrode 64.

Correspondingly, the fabrication method of the sensor may further include S41 to S51 to S56.

In S51, a second glass substrate may be provided. The second glass substrate may include a phase shifter portion and a portion to be cut.

In S52, a first electrode may be formed at a side of the phase shifter portion.

In S53, the phase shifter portion may include a first phase shifter portion and a second phase shifter portion. A transmitting antenna array may be formed at a side of the first phase shifter portion away from the first electrode, and a receiving antenna array may be formed at a side of the second phase shifter portion away from the second electrode.

In S54, the first glass substrate and the second glass substrate may be aligned to form a cell, such that the portion to be cut corresponds to an extension portion of the first glass substrate. A liquid crystal layer may be formed between the first glass substrate and the phase shifter portion. The first electrode may be located at the side of the phase shifter portion close to the first glass substrate, and the second electrode may be located on a side of the first glass substrate close to the phase shifter portion.

As shown in FIG. 17, after the first glass substrate 10 and the second glass substrate 61 are aligned to form the cell, the portion to be cut 612 may correspond to the extension portion 11 of the first glass substrate 10. The liquid crystal layer 62 may be formed between the first glass substrate 10 and the phase shifter portion 611. The first electrode may be located at the side of the phase shifter portion close to the first glass substrate, and the second electrode may be located on the side of the first glass substrate close to the phase shifter portion. Therefore, a phase shifter may be integrated into the first glass substrate 10.

Also, the phase shifter 60 may include the first phase shifter 601 and the second phase shifter 602. The transmitting antenna array 40 may be disposed at the side of the first phase shifter portion away from the first glass substrate 10, and the receiving antenna array 50 may be disposed on the side of the second phase shifter portion away from the first glass substrate 10. Therefore, the transmitting antenna array 40 and the receiving antenna array 50 may be also integrated into the first glass substrate 10.

In S55, the portion to be cut of the second glass substrate may be cut and removed, such that the extension portion does not overlap with the second glass substrate along a direction perpendicular to the plane where the first glass substrate is located.

As shown in FIG. 18, after the first glass substrate 10 and the second glass substrate 61 are aligned to form the cell, the portion to be cut of the second glass substrate 61 may be cut and removed and only the phase shifter portion 611 may be preserved in the second glass substrate 61. Along the direction perpendicular to the plane where the first glass substrate 10 is located, the extension portion 11 may not overlap with the second glass substrate 61, to facilitate subsequent integration of other components on the extension portion 11.

In S56, the radio frequency processing chip may be bonded and connected on the side of the circuit layer away from the extension portion.

In the present embodiment, a portion of the first glass substrate 10 corresponding to the second glass substrate 61 may be arranged opposite to the second glass substrate 61, and the liquid crystal layer 62 may be disposed between the portion of the first glass substrate 10 corresponding to the second glass substrate 61 and the second glass substrate 61, such that the phase shifter 60 is formed on the first glass substrate 10. Further, the first glass substrate 10 may include the extension portion 11 that does not overlap with the second glass substrate 61 along the direction perpendicular to the plane where the first glass substrate 10 is located. The radio frequency processing chip 30 may be disposed on the side of the circuit layer 20 away from the extension portion 11. Therefore, the radio frequency processing chip 30 may be integrated on the first glass substrate 10, and the integration degree of the sensor may be improved.

Also, the phase shifter 60 may include the first phase shifter 601 and the second phase shifter 602. The transmitting antenna array 40 may be disposed on the side of the second glass substrate 61 in the first phase shifter 601 away from the first glass substrate 10, and the receiving antenna array 50 may be disposed on the side of the second glass substrate 61 in the second phase shifter 602 away from the first glass substrate 10. Therefore, the transmitting antenna array 40 and the receiving antenna array 50 may be also integrated into the first glass substrate 10, and the integration degree of the sensor may be improved. Also, the transmitting antenna array 40 may be disposed on the side of the second glass substrate 61 in the first phase shifter 601 away from the first glass substrate 10, such that the second glass substrate 61 in the first phase shifter 601 may be multiplexed to integrate the transmitting antenna array 40. The receiving antenna array 50 may be disposed on the side of the second glass substrate 61 in the second phase shifter 602 away from the first glass substrate 10, such that the second glass substrate 61 in the second phase shifter 602 may be multiplexed to integrate the receiving antenna array 50. The volume of the sensor may be reduced.

In some embodiments, the method may further include:
forming a support column at a side of the portion to be cut, where the support column may be located between the first glass substrate and the portion to be cut; and
when cutting and removing the portion to be cut of the second glass substrate, also removing the support column.

As shown in FIG. 14 and FIG. 17, the support column S may be formed at the side of the portion to be cut 612, and the support column S may be located between the first glass substrate 10 and the portion to be cut 612 when the first glass substrate 10 and the second glass substrate 61 are aligned into the cell. The support column S may support the portion to be cut 612 and prevent the portion to be cut from tilting or collapsing before the portion to be cut 612 is cut. Optionally, the support column S may include a main support column S1 and an auxiliary support column S2. Along the direction perpendicular to the plane where the first glass substrate 10 is located, the height of the main support column S1 may be larger than the height of the auxiliary support column S2. The main support column S1 may be firstly used to support the portion to be cut 612, When cutting the portion to be cut 612, the auxiliary support column S2 may be used to provide further auxiliary support for the portion to be cut 612. The portion to be cut 612 may be supported better and the cutting of the portion to be cut 612 may be facilitated.

As shown in FIG. 15 and FIG. 18, when cutting and removing the portion to be cut of the second glass substrate 61, the support column may be removed at the same time, such that the subsequent integration of other components on the extension portion 11 may not be affected.

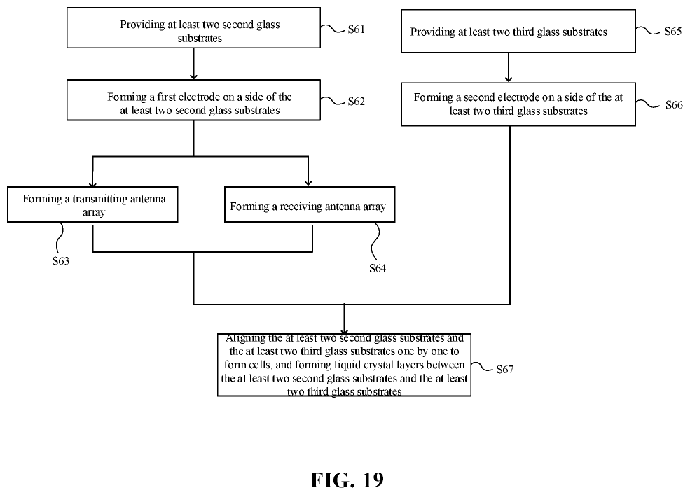

FIG. 19 shows a flowchart of another fabrication method of a sensor provided by another embodiment of the present disclosure. As shown in FIG. 19, in some embodiments, the method may further include:
S61: providing at least two second glass substrates;
S62: forming a first electrode on a side of the at least two second glass substrates;
S63: forming a transmitting antenna array at a side of one of the at least two second glass substrates away from the first electrode;
S64: forming a receiving antenna array at a side of one of the at least two second glass substrates away from the first electrode;
S65: providing at least two third glass substrates;
S66: forming a second electrode on a side of the at least two third glass substrates;
S67: aligning the at least two second glass substrates and the at least two third glass substrates one by one to form cells, and forming liquid crystal layers between the at least two second glass substrates and the at least two third glass substrates. The first electrode may be located on the side of the at least two second glass substrates close to the at least two third glass substrates, and the second electrode may be located on the side of the at least two third glass substrates close to the at least two second glass substrates.

In the present embodiment, the at least two second glass substrates 61 and the at least two third glass substrates 65 may be disposed oppositely to each other, and the liquid crystal layers 62 may be disposed between the at least two second glass substrates 61 and the at least two third glass substrate 65s. That is, the phase shifter 60 and the radio frequency processing chip 30 may be disposed on different glass substrates. The phase shifter 60 and the radio frequency processing chip 30 may be mutually independent structures, and may be connected or replaced more flexibly according to usage requirements. Further, the manufacturing of the phase shifter 60 and the bonding of the radio frequency processing chip 30 may be manufactured separately, which is beneficial to reduce the difficulty of the process.

The phase shifter 60 may further include the first phase shifter 601 and the second phase shifter 602. The transmitting antenna array 40 may be located on the side of one second glass substrate 61 of the at least two second glass substrate 61 in the first phase shifter 601 away from the third glass substrate 65. The receiving antenna array 50 may be located on the side one second glass substrate 61 of the at least two second glass substrates 61 in the second phase shifter 602 away from the third glass substrate 65. The second glass substrate 61 in the first phase shifter 601 may be multiplexed to integrate the transmitting antenna array 40, and the second glass substrate 61 in the second phase shifter 602 may be multiplexed to integrate the receiving antenna array 50. The volume of the sensor may be reduced.

One of the at least two third glass substrates 65 in the first phase shifter 601 and one of the at least two third glass be different glass substrates. The second glass substrate 61 in the first phase shifter 601 and the second glass substrate 61 in the second phase shifter 602 may be different glass substrates. That is, the first phase shifter 601 and the second phase shifter 602 may be structures independent from each other, and may be connected or replaced more flexibly according to the user requirements. The first phase shifter 601 and the second phase shifter 602 may be manufactured separately, and the manufacturing process may be more mature, which is beneficial to reducing the difficulty of the process.

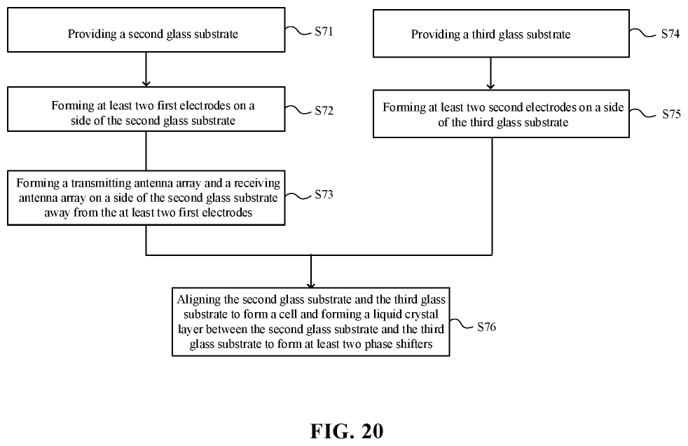

FIG. 20 shows a flowchart of another fabrication method of a sensor provided by another embodiment of the present disclosure. As shown in FIG. 20, in some embodiments, the method may further include:
S71: providing a second glass substrate;
S72: forming at least two first electrodes on a side of the second glass substrate;
S73: forming a transmitting antenna array and a receiving antenna array on a side of the second glass substrate away from the at least two first electrodes, where the transmitting antenna array and the receiving antenna array may correspond to different first electrodes of the at least two first electrodes respectively;
S74: providing a third glass substrate;
S75: forming at least two second electrodes on a side of the third glass substrate; and
S76: aligning the second glass substrate and the third glass substrate to form a cell, and forming a liquid crystal layer between the second glass substrate and the third glass substrate to form at least two phase shifters.

The at least two the first electrodes and the at least two second electrodes may have a one-to-one correspondence. The at least two first electrodes may be located on the side of the second glass substrate close to the third glass substrate, and the at least two second electrodes may be located on the side of the third glass substrate close to the second glass substrate.

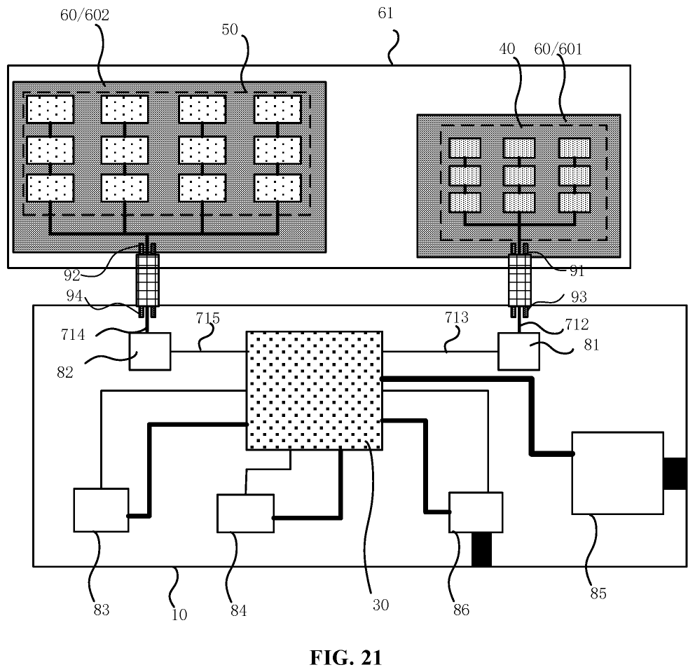

FIG. 21 shows a planar schematic diagram formed by the method in the present embodiment. As shown in FIG. 10, FIG. 11, and FIG. 21, the second glass substrate 61 and the third glass substrate 65 may be arranged oppositely, and the liquid crystal layer 62 may be disposed between the second glass substrate 61 and the third glass substrate 65. The at least two phase shifters 60 may be formed by the second glass substrate 61 and the third glass substrate 65. In this embodiment, the at least two phase shifters 60 and the radio frequency processing chip 30 may be arranged on different glass substrates. That is, the at least two phase shifters 60 and the radio frequency processing chip 30 may be mutually independent structures, and may be connected or replaced more flexibly according to usage requirements. Also, the manufacturing of the at least two phase shifters 60 and the bonding of the radio frequency processing chip 30 may be manufactured separately, which is beneficial to reduce the difficulty of the process.

Also, the at least two phase shifters 60 may include a first phase shifter 601 and a second phase shifter 602. The transmitting antenna array 40 may be located on the side of the second glass substrate 61 in the first phase shifter 601 away from the third glass substrate 65, and the receiving antenna array 50 may be located on the side of the second glass substrate 61 in the second phase shifter 602 away from the third glass substrate 65. The second glass substrate 61 in the first phase shifter 601 may be multiplexed to integrate the transmitting antenna array 40, and the second glass substrate 61 in the second phase shifter 602 may be multiplexed to integrate the receiving antenna array 50. The volume of the sensor may be reduced.

Also, the third glass substrate 65 in the first phase shifter 601 and the third glass substrate 65 in the second phase shifter 602 may be the same glass substrate, that is, the first phase shifter 601 and the second phase shifter 602 may be integrated in the same glass substrate, improving the integration level.

In the sensor or the fabrication method provided by various embodiments of the present disclosure, the radio frequency processing chip may be bonded on the first glass substrate, and the circuit layer may be fabricated on the first glass substrate by a panel process with high flatness and low film layer roughness. That is, the minimum line width of wirings in the circuit layer on the first glass substrate may be set smaller. For example, the exemplary minimum line width of the wirings in the circuit layer on the first glass substrate may be set to about 5 μm, such that the film layer roughness of the wirings provided on the first glass substrate may be on the order of tens of nm and the film roughness of each wiring layer in the circuit layer may be small. Correspondingly, when the radio frequency processing chip is bonded to the first glass substrate, the radiation loss of the radio frequency signals may be effectively reduced and the detection accuracy may be improved.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A sensor, comprising:
a first glass substrate;
a circuit layer on a side of the first glass substrate; and
a radio frequency processing chip on a side of the circuit layer away from the first glass substrate.

2. The sensor according to claim 1, further comprising a transmitting antenna array, a receiving antenna array, and a phase shifter, wherein:
the transmitting antenna array, the receiving antenna array, and the phase shifter are all located on the side of the circuit layer away from the first glass substrate.

3. The sensor according to claim 2, wherein:
the phase shifter includes a second glass substrate corresponding to the first glass substrate, and a liquid crystal layer located between the first glass substrate and the second glass substrate;
the first glass substrate includes an extension portion, wherein the extension portion does not overlap with the second glass substrate along a direction perpendicular to a plane where the first glass substrate is located;
the transmitting antenna array, the receiving antenna array, and the radio frequency processing chip are all located on the side of the circuit layer away from the extension portion; and
the transmitting antenna array and the receiving antenna array are both electrically connected to the phase shifter, and the phase shifter is electrically connected to the radio frequency processing chip.

4. The sensor according to claim 3, wherein:
the phase shifter further includes a first electrode and a second electrode, wherein the first electrode is located on a side of the second glass substrate close to the first glass substrate;
the transmitting antenna array is electrically connected to the second electrode through a first wiring;
the receiving antenna array is electrically connected to the second electrode through a second wiring;
the second electrode is electrically connected to the radio frequency processing chip through a third wiring;
the circuit layer includes a first metal layer on the side of the circuit layer away from the first glass substrate; and
the transmitting antenna array, the receiving antenna array, the first wiring, the second wiring, the third wiring and the second electrode are all located in the first metal layer.

5. The sensor according to claim 4, further comprising a transmitting antenna power amplifier and a low noise amplifier, wherein:
the transmitting antenna power amplifier and the low noise amplifier are both located on the side of the circuit layer away from the extension portion;
the transmitting antenna power amplifier is electrically connected to the second electrode through a fourth wiring, and is electrically connected to the radio frequency processing chip through a fifth wiring;
the low noise amplifier is electrically connected to the second electrode through a sixth wiring, and is electrically connected to the radio frequency processing chip through a seventh wiring;
the circuit layer further includes a second metal layer between the first metal layer and the first glass substrates; and
the fourth wiring to the seventh wiring are all located in the second metal layer.

6. The sensor according to claim 2, wherein:
the phase shifter includes a second glass substrate corresponding to the first glass substrate, and a liquid crystal layer located between the first glass substrate and the second glass substrate;
the first glass substrate includes an extension portion, wherein the extension portion does not overlap with the second glass substrate along a direction perpendicular to a plane where the first glass substrate is located;
the radio frequency processing chip is located on the side of the circuit layer away from the extension portion;
the phase shifter includes a first phase shifter and a second phase shifter, wherein the transmitting antenna array is located on a side of the second glass substrate in the first phase shifter away from the first glass substrate and the receiving antenna array is located on a side of the second glass substrate in the second phase shifter away from the first glass substrate; and
the transmitting antenna array and the receiving antenna array are both electrically connected to the radio frequency processing chip.

7. The sensor according to claim 6, wherein:
the phase shifter further includes a first electrode and a second electrode, wherein the first electrode is located on a side of the second glass substrate close to the first glass substrate;
the circuit layer includes a first metal layer on the side of the circuit layer away from the first glass substrate; and
the second electrode is located in the first metal layer.

8. The sensor according to claim 7, further comprising a transmitting antenna power amplifier and a low noise amplifier, wherein:
the transmitting antenna power amplifier and the low noise amplifier are both located on the side of the circuit layer away from the extension portion;
the transmitting antenna power amplifier is electrically connected to the transmitting antenna array through an eighth wiring, and is electrically connected to the radio frequency processing chip through a ninth wiring;
the low noise amplifier is electrically connected to the receiving antenna array through a tenth wiring, and is electrically connected to the radio frequency processing chip through an eleventh wiring;
the circuit layer further includes a second metal layer between the first metal layer and the first glass substrates;
the eighth wiring and the tenth wiring are located in the first metal layer; and
the ninth wiring and the eleventh wiring are located in the second metal layer.

9. The sensor according to claim 1, further comprising a transmitting antenna array, a receiving antenna array, and a phase shifter, wherein:
the phase shifter includes a second glass substrate corresponding to the third glass substrate, a liquid crystal layer located between the third glass substrate and the second glass substrate, a first electrode, and a second electrode, wherein the first electrode is located on a side of the second glass substrate close to the third glass substrate and the second electrode is located on a side of the third glass substrate close to the second glass substrate;
the phase shifter includes a first phase shifter and a second phase shifter;
the transmitting antenna array is located on a side of the second glass substrate in the first phase shifter away from the third glass substrate; and
the receiving antenna array is located on a side of the second glass substrate in the second phase shifter away from the third glass substrate.

10. The sensor according to claim 9, wherein:
the third glass substrate in the first phase shifter is provided with a first radio frequency connector electrically connected to the transmitting antenna array;
the third glass substrate in the second phase shifter is provided with a second radio frequency connector electrically connected to the receiving antenna array;
the side of the circuit layer away from the first glass substrate is provided with a third radio frequency connector and a fourth radio frequency connector; and
the first radio frequency connector is electrically connected to the third radio frequency connector through a first coaxial cable, and the second radio frequency connector is electrically connected to the fourth radio frequency connector through a second coaxial cable.

11. The sensor according to claim 10, further comprising a transmitting antenna power amplifier and a low noise amplifier, wherein:
the transmitting antenna power amplifier and the low noise amplifier are both located on the side of the circuit layer away from the first glass substrate;
the transmitting antenna power amplifier is electrically connected to the third radio frequency connector through a twelfth wiring, and is electrically connected to the radio frequency processing chip through a thirteenth wiring;
the low noise amplifier is electrically connected to the fourth radio frequency connector through a fourteenth wiring, and is electrically connected to the radio frequency processing chip through a fifteenth wiring;
the circuit layer includes a first metal layer and a second metal layer, wherein the second metal layer is located between the first metal layer and the first glass substrate;
the twelfth wiring and the fourteenth wiring are located on the first metal layer; and
the thirteenth wire and the fifteenth wire are located on the second metal layer.

12. The sensor according to claim 1, further comprising a resistance module, a capacitive device module, a power supply module, and an I/O chip, wherein:
the resistance module, the capacitive device module, the power supply module, and the I/O chip are all electrically connected to the radio frequency processing chip.

13. The sensor according to claim 1, wherein:
the circuit layer includes a plurality of metal layers and a plurality of insulating layers;
at least one insulating layer of the plurality of insulating layers is arranged between two adjacent metal layers of the plurality of metal layers;
the plurality of insulating layers is made of a material including polyimide; and
the plurality of metal layers is made of a material including copper, silver, gold, or a combination thereof.

14. The sensor according to claim 1, wherein:
the circuit layer includes a plurality of signal wires and a plurality of ground wires;
the plurality of signal wires is electrically connected to the radio frequency processing chip;
a vertical projection of one of the plurality of signal wires on the first glass substrate is located within a vertical projection of a corresponding one of the plurality of ground wires on the first glass substrate.

15. A fabrication method of a sensor, comprising:
providing a first glass substrate;
forming a circuit layer on a side of the first glass substrate; and
bonding and connecting a radio frequency processing chip on a side of the circuit layer away from the first glass substrate.

16. The method according to claim 15, wherein:
the circuit layer includes a first metal layer on the side of the circuit layer away from the first glass substrate;
the first metal layer includes a transmitting antenna array, a receiving antenna array, and a second electrode; and
the method further includes:
providing a second glass substrate, wherein the second glass substrate includes a phase shifter portion and a portion to be cut;
forming a first electrode on a side of the phase shifter portion;
aligning the first glass substrate and the second glass substrate to form a cell and forming a liquid crystal layer between the first glass substrate and the phase shifter portion, wherein the portion to be cut corresponds to the extension portion of the first glass substrate, the first electrode is located on a side of the phase shifter portion close to the first glass substrate, and the second electrode is located on a side of the first glass substrate close to the phase shifter portion;
cutting and removing the portion to be cut of the second glass substrate, such that the extension portion does not overlap with the second glass substrate along a direction perpendicular to a plane where the first glass substrate is located; and
bonding and connecting the radio frequency processing chip on a side of the circuit layer away from the extension portion.

17. The method according to claim 15, wherein:
the circuit layer includes a first metal layer on the side of the circuit layer away from the first glass substrate;
the first metal layer includes a second electrode; and
the method further includes:
providing a second glass substrate, wherein the second glass substrate includes a phase shifter portion and a portion to be cut, and the phase shifter portion includes a first phase shifter portion and a second phase shifter portion;
forming a first electrode on a side of the phase shifter portion;
forming a transmitting antenna array on a side of the first phase shifter portion away from the first electrode and a receiving antenna array on a side of the second phase shifter portion away from the first electrode;
aligning the first glass substrate and the second glass substrate to form a cell and forming a liquid crystal layer between the first glass substrate and the phase shifter portion, wherein the portion to be cut corresponds to the extension portion of the first glass substrate, the first electrode is located on a side of the phase shifter portion close to the first glass substrate, and the second electrode is located on a side of the first glass substrate close to the phase shifter portion;
cutting and removing the portion to be cut of the second glass substrate, such that the extension portion does not overlap with the second glass substrate along a direction perpendicular to a plane where the first glass substrate is located; and
bonding and connecting the radio frequency processing chip on a side of the circuit layer away from the extension portion.

18. The method according to claim 16, further comprising:
forming a support column on a side of the portion to be cut, such that the support column is located between the first glass substrate and the portion to be cut when the first glass substrate and the second glass substrate are aligned to form the cell; and
when cutting and removing the portion to be cut of the second glass substrate, removing the support column at the same time.

19. The method according to claim 15, further comprising:
providing at least two second glass substrates;
forming a first electrode on a side of the at least two second glass substrates;
forming a transmitting antenna array at a side of one of the at least two second glass substrates away from the first electrode;
forming a receiving antenna array at a side of one of the at least two second glass substrates away from the first electrode;
providing at least two third glass substrates;
forming a second electrode on a side of the at least two third glass substrates; and
aligning the at least two second glass substrates and the at least two third glass substrates one by one to form cells, and forming liquid crystal layers between the at least two second glass substrates and the at least two third glass substrates, wherein the first electrode is located on a side of the at least two second glass substrates close to the at least two third glass substrates and the second electrode is located on a side of the at least two third glass substrates close to the at least two second glass substrates.

20. The method according to claim 15, further comprising:
providing a second glass substrate;
forming at least two first electrodes on a side of the second glass substrate;
forming a transmitting antenna array and a receiving antenna array on a side of the second glass substrate away from the at least two first electrodes, wherein the transmitting antenna array and the receiving antenna array correspond to different first electrodes of the at least two first electrodes respectively;
providing a third glass substrate;
forming at least two second electrodes on a side of the third glass substrate; and
aligning the second glass substrate and the third glass substrate to form a cell and forming a liquid crystal layer between the second glass substrate and the third glass substrate to form at least two phase shifters, wherein the at least two first electrodes and the at least two second electrodes have a one-to-one correspondence, the at least two first electrodes are located on the side of the second glass substrate close to the third glass substrate, and the at least two second electrodes are located on the side of the third glass substrate close to the second glass substrate.
